(19) United States
(12) Patent Application Publication
(10) Pub. No.: US 2021/0175242 A1
(43) Pub. Date: Jun. 10, 2021

(54) SEMICONDUCTOR MEMORY DEVICE AND MANUFACTURING METHOD OF THE SEMICONDUCTOR MEMORY DEVICE

(71) Applicant: SK hynix Inc., Icheon-si Gyeonggi-do (KR)

(72) Inventor: Jin Ha KIM, Icheon-si Gyeonggi-do (KR)

(73) Assignee: SK hynix Inc., Icheon-si Gyeonggi-do (KR)

(21) Appl. No.: 16/884,903

(22) Filed: May 27, 2020

(30) Foreign Application Priority Data
Dec. 9, 2019 (KR) 10-2019-0162380

(51) Int. Cl. H01L 27/11556; H01L 27/11519; H01L 27/11565; H01L 27/11582

(52) U.S. Cl. CPC H01L 27/11556; H01L 27/11582; H01L 27/11565; H01L 27/11519

(57) ABSTRACT

A method of manufacturing a semiconductor memory device includes: forming sacrificial patterns and insulating patterns, which are alternately stacked on a source structure; forming channel structures penetrating the sacrificial patterns and the insulating patterns; forming a first trench and a second trench, which penetrate the sacrificial patterns and the insulating patterns; replacing the sacrificial patterns with conductive patterns through the first and second trenches; and forming gate isolation layers, which penetrate some of the conductive patterns and some of the insulating patterns, and are located between the first trench and the second trench. The insulating patterns include a second insulating pattern and first insulating patterns between the second insulating pattern and the source structure. Lowermost portions of the gate isolation layers are located in the second insulating pattern. The second insulating pattern has a thickness thicker than those of the first insulating patterns.

### CROSS-REFERENCE TO RELATED APPLICATION

The present application claims priority under 35 U.S.C. § 119(a) to Korean patent application number 10-2019-0162380 filed on Dec. 9, 2019, the entire disclosure of which is incorporated herein by reference.

### BACKGROUND

### 1. Technical Field

The present disclosure generally relates to a semiconductor memory device and a manufacturing method of the semiconductor memory device, and more particularly, to a three-dimensional semiconductor memory device and a manufacturing method of the three-dimensional semiconductor memory device.

### 2. Related Art

A semiconductor memory device includes memory cells capable of storing data.

According to a method of storing data and a method of retaining data, the semiconductor memory device may be classified into a volatile semiconductor memory device and a nonvolatile semiconductor memory device. The volatile semiconductor memory device is a memory device in which stored data disappears when the supply of power is interrupted, and the nonvolatile semiconductor memory device is a memory device in which stored data is retained even when the supply of power is interrupted.

Recently, as portable electronic devices are increasingly used, nonvolatile semiconductor memory devices have been increasingly used, and the high integration and large capacity of semiconductor memory devices have been required to achieve portability and large capacity. In order to achieve the portability and large capacity, there have been proposed three-dimensional semiconductor memory devices.

### SUMMARY

In accordance with an aspect of the present disclosure, there is provided a method of manufacturing a semiconductor memory device, the method may include: forming sacrificial patterns and insulating patterns, which are alternately stacked on a source structure; forming channel structures penetrating the sacrificial patterns and the insulating patterns; forming a first trench and a second trench, which penetrate the sacrificial patterns and the insulating patterns; replacing the sacrificial patterns with conductive patterns through the first and second trenches; and forming gate isolation layers, which penetrate some of the conductive patterns and some of the insulating patterns, and are located between the first trench and the second trench, wherein the insulating patterns include a second insulating pattern and first insulating patterns between the second insulating pattern and the source structure, wherein lowermost portions of the gate isolation layers are located in the second insulating pattern, wherein the second insulating pattern has a thickness thicker than those of the first insulating patterns.

In accordance with another aspect of the present disclosure, there is provided a semiconductor memory device which may include: a stack structure including conductive patterns and insulating patterns, which are alternately stacked; first and second slit structures spaced apart from each other with the stack structure interposed between the first and second slit structures; a first gate isolation layer penetrating a portion of the stack structure, the first gate isolation layer being disposed between the first slit structure and the second slit structure; a second gate isolation layer penetrating a portion of the stack structure, the second gate isolation layer being disposed between the first slit structure and the second slit structure; and first channel structures penetrating the stack structure, the first channel structures being disposed between the first gate isolation layer and the second gate isolation layer, wherein the insulating patterns include a second insulating pattern in contact with lowermost portions of the first and second gate isolation layers and first insulating patterns spaced apart from the first and second gate isolation layers, wherein the second insulating pattern has a thickness thicker than those of the first insulating patterns.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1A is a plan view of a semiconductor memory device in accordance with a first embodiment of the present disclosure.

FIG. 1B is a sectional view taken along line A-A′ shown in FIG. 1A.

FIG. 1C is an enlarged view of region B shown in FIG. 1B.

FIG. 2A is a sectional view of a semiconductor memory device in accordance with a second embodiment of the present disclosure.

FIG. 2B is an enlarged view of region C shown in FIG. 2A.

FIGS. 3A, 3B, 3C, 3D, and 3E are sectional views illustrating a manufacturing method of the semiconductor memory device in accordance with the first embodiment of the present disclosure.

FIG. 4 is a block diagram illustrating a configuration of a memory system in accordance with an embodiment of the present disclosure.

FIG. 5 is a block diagram illustrating a configuration of a computing system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

It will be understood that, although the terms first, second, third etc. may be used herein to describe various elements, patterns, components, regions, layers and/or sections, these elements, patterns, components, regions, layers and/or sections should not be limited by these terms. These terms are only used to distinguish one element, pattern, component, region, layer or section from another region, layer or section. Thus, a first element, pattern, component, region, layer or section discussed below could be termed a second element, pattern, component, region, layer or section without departing from the teachings of the present disclosure.

Embodiments provide a semiconductor memory device capable of improving operational reliability and a manufacturing method of the semiconductor memory device.

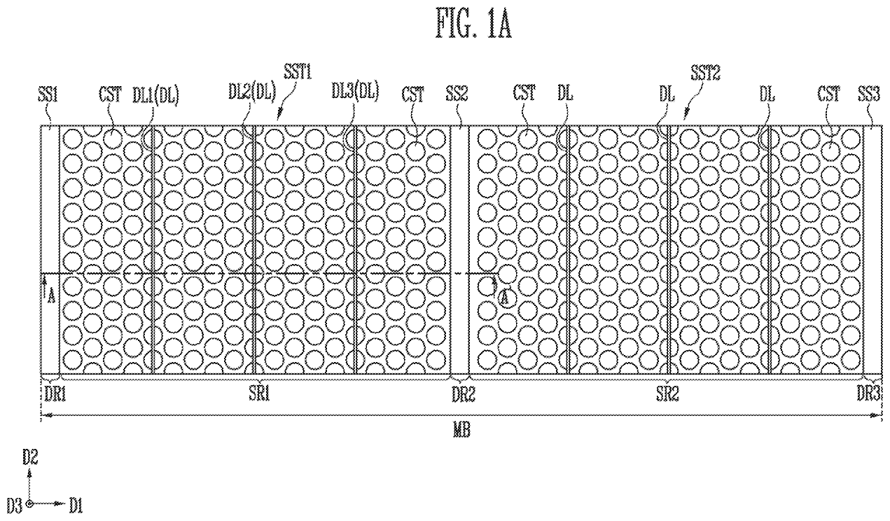

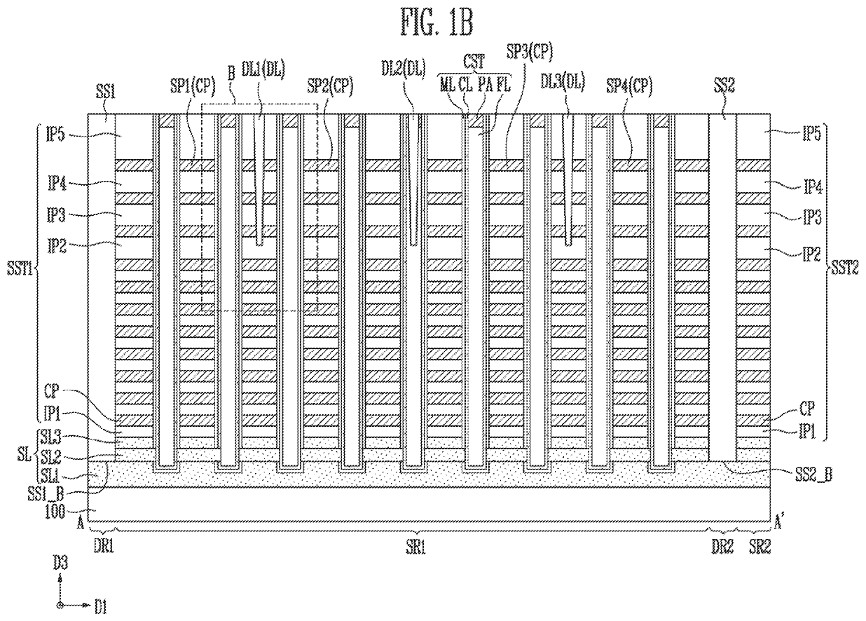

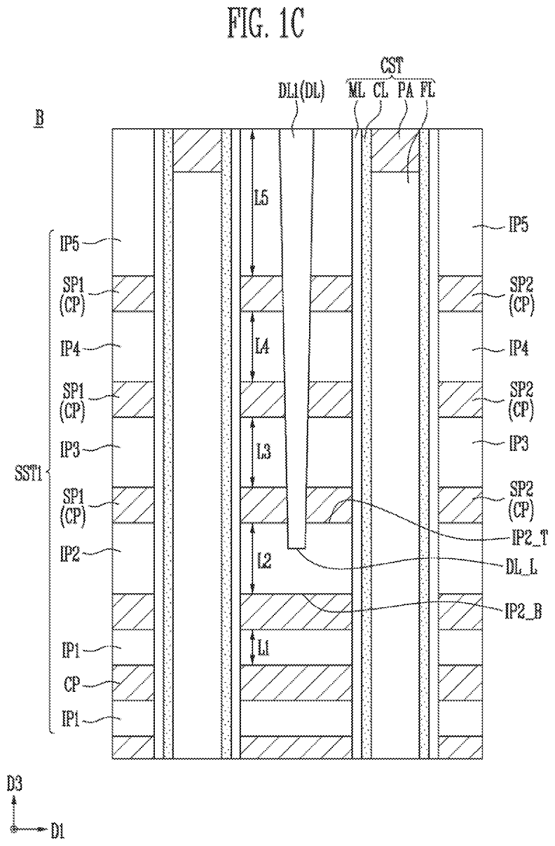

FIG. 1A is a plan view of a semiconductor memory device in accordance with a first embodiment of the present disclosure. FIG. 1B is a sectional view taken along line A-A′ shown in FIG. 1A. FIG. 1C is an enlarged view of region B shown in FIG. 1B.

Referring to FIGS. 1A to 1C, the semiconductor memory device in accordance with these embodiments may include a substrate 100. The substrate 100 may have the shape of a plate expanding along a plane defined by a first direction D1 and a second direction D2. A direction protruding from the plane may be defined as a third direction D3. In an example, the third direction D3 may be perpendicular to the plane. The first to third directions D1, D2, and D3 may intersect one another.

The substrate 100 may include a first isolation region DR1, a first stack region SR1, a second isolation region DR2, a second stack region SR2, and a third isolation region DR3. The first isolation region DR1, the first stack region SR1, the second isolation region DR2, the second stack region SR2, and the third isolation region DR3 may be sequentially arranged along the first direction D1. The first stack region SR1 may be disposed between the first and second isolation regions DR1 and DR2, and the second stack region SR2 may be disposed between the second and third isolation regions DR2 and DR3.

The substrate 100 may be a single crystalline semiconductor substrate. For example, the substrate 100 may be a bulk silicon substrate, a silicon on insulator substrate, a germanium substrate, a germanium on insulator substrate, a silicon-germanium substrate, or an epitaxial thin film formed through a selective epitaxial growth process.

A source structure SL may be provided on the first and second stack regions SR1 and SR2 and the second isolation region DR2. The source structure SL may include a conductive material. In an example, the source structure SL may include poly-silicon.

Although not shown in the drawings, a peripheral circuit structure and a connection structure may be provided between the source structure SL and the substrate 100. The peripheral circuit structure may include NMOS transistors, PMOS transistors, a resistor, and a capacitor. The NMOS transistors, the PMOS transistors, the resistor, and the capacitor may be used as elements constituting a row decoder, a column decoder, a page buffer circuit, and an input/output circuit. The connection structure may include a contact plug and a line.

In an example, as shown in the drawings, the source structure SL may include first to third source layers SL1, SL2, and SL3. In another example, unlike as shown in the drawings, the source structure SL may be configured in a single layer. Hereinafter, although a case where the source structure SL includes the first to third source layers SL1, SL2, and SL3 is described as an example, the structure of the source structure SL may not be limited thereto.

The first source layer SL1 may have the shape of a plate expanding along a plane defined by the first direction D1 and the second direction D2.

The second source layers SL2 may be provided on the first source layer SL1. The second source layers SL2 may have the shape of a plate expanding along a plane defined by the first direction D1 and the second direction D2. Each of the second source layers SL2 may be provided on the first stack region SR1 or the second stack region SR2.

The third source layers SL3 may be provided on the second source layers SL2, respectively. The third source layers SL3 may have the shape of a plate expanding along a plane defined by the first direction D1 and the second direction D2.

A first slit structure SS1 may be provided on the first isolation region DR1, a second slit structure SS2 may be provided on the second isolation region DR2, and a third slit structure SS3 may be provided on the third isolation region DR3. The first to third slit structures SS1, SS2, and SS3 may extend in the second direction D2 and the third direction D3. The first to third slit structures SS1, SS2, and SS3 may be in contact with the source structure SL. The second and third source layers SL2 and SL3 may be provided between the first and second slit structures SS1 and SS2. The second and third source layers SL2 and SL3 may be provided between the second and third slit structures SS2 and SS3.

At least one of the first to third slit structures SS1, SS2, and SS3 may include an insulating material. In an example, the insulating material may include silicon oxide. At least one of the first to third slit structures SS1, SS2, and SS3 may include a common source line and source insulating layers. The source insulating layers may be spaced apart from each other in the first direction D1 with the common source line interposed therebetween. The source insulating layers may electrically isolate the common source line from conductive patterns CP which will be described later. The common source line may be in contact with the first source layer SL1 and the second source layer SL2. The common source line may include a conductive material. In an example, the common source line may include at least one of tungsten and doped poly-silicon. In an example, the source insulating layers may include silicon oxide.

A first stack structure SST1 may be provided on the first stack region SR1, and a second stack structure SST2 may be provided on the second stack region SR2. The first stack structure SST1 may be provided between the first and second slit structures SS1 and SS2, and the second stack structure SST2 may be provided between the second and third slit structures SS2 and SS3. The first and second stack structures SST1 and SST2 may be spaced apart from each other in the first direction D1 by the second slit structure SS2. In other words, the first and second stack structures SST1 and SST2 may be isolated from each other by the second slit structure SS2. The first and second slit structures SS1 and SS2 may be spaced apart from each other in the first direction D1 with the first stack structure SST1 interposed therebetween. The second and third slit structures 552 and SS3 may be spaced apart from each other in the first direction D1 with the second stack structure SST2 interposed therebetween.

The first to third slit structures SS1, SS2, and SS3 and the first and second stack structures SST1 and SST2 may constitute one memory block MB. An erase operation of the semiconductor memory device may be performed in a unit of the memory block MB.

Each of the first and second stack structures SST1 and SST2 may include first to fifth insulating patterns IP1, IP2, IP3, IP4, and IP5 and the conductive patterns CP.

In each of the first and second stack structures SST1 and SST2, the first to fifth insulating patterns IP1, IP2, IP3, IP4, and IP5 may be sequentially arranged to be space apart from each other along the third direction D3. Among the first to fifth insulating patterns IP1, IP2, IP3, IP4, and IP5, the first insulating patterns IP1 may be arranged along the third direction D3 from a lowermost portion to an intermediate portion of the first stack structure SST1 or the second stack structure SST2, and the fifth insulating patterns IP5 may be disposed at an uppermost portion of the first stack structure SST1 or the second stack structure SST2. The second to fourth insulating patterns IP2, IP3, and IP4 may be disposed between the first and fifth insulating patterns IP1 and IP5. The first insulating patterns IP1 may be disposed under the second insulating pattern IP2, the third insulating patterns IP3 may be disposed above the second insulating pattern IP2, and the fourth insulating patterns IP4 may be disposed above the third insulating patterns IP3. The first insulating patterns IP1 may be disposed between the second insulating pattern IP2 and the substrate 100 or between the second insulating pattern IP2 and the source structure SL.

The conductive patterns CP may be alternately stacked with the first to fifth insulating patterns IP1, IP2, IP3, IP4, and IP5.

In an example, the first to fifth insulating patterns IP1, IP2, IP3, IP4, and IP5 may include silicon oxide. The conductive patterns CP may include a gate conductive layer. In an example, the gate conductive layer may include at least one of a doped silicon layer; a metal silicide layer, tungsten, nickel, and cobalt, and be used as a word line connected to a memory cell or a select line connected to a select transistor. The conductive patterns CP may further include a gate barrier layer surrounding the gate conductive layer. In an example, the gate barrier layer may include at least one of titanium nitride and tantalum nitride.

Gate isolation layers DL penetrating an upper portion of the first stack structure SST1 or the second stack structure SST2 may be provided. The gate isolation layers DL may penetrate some of the first to fifth insulating patterns IP1, IP2, IP3, IP4, and IP5 and some of the conductive patterns CR The conductive patterns CP may include select lines SP1, SP2, SP3, and SP4, and include word lines. The select lines SP1, SP2, SP3, and SP4 may be penetrated by the gate isolation layers DL. The word lines may not be penetrated by the gate isolation layers DL.

The gate isolation layers DL may be provided in the first stack structure SST1 or the second stack structure SST2. The gate isolation layers DL may extend in the second direction D2.

A plurality of gate isolation layers DL may penetrate an upper portion of one stack structure SST1 or SST2. In other words, the plurality of gate isolation layers DL may be disposed between the first and second slit structures SS1 and SS2 or between the second and third slit structures SS2 and SS3. For example, the gate isolation layers DL penetrating the first stack structure SST1 may include first to third gate isolation layers DL1, DL2, and DL3. The first to third gate isolation layers DL1, DL2, and DL3 may be arranged to be spaced apart from each other in the first direction D1. The first to third gate isolation layers DL1, DL2, and DL3 may be disposed between the first and second slit structures SS1 and SS2.

The gate isolation layer DL may penetrate an upper portion of a channel structure CST which will be described later. In an example, the gate isolation layer DL may include silicon oxide.

A lowermost portion DL_L of the gate isolation layer DL may be in contact with the second insulating pattern IP2. The lowermost portion DL_L of the gate isolation layer DL may be located in the second insulating pattern IP2. A level of the lowermost portion DL_L of the gate isolation layer DL may be lower than that of an upper surface IP2_T of the second insulating pattern IP2, and be higher than that of a lower surface IP2_B of the second insulating pattern IP2. The lowermost portion DL_L of the gate isolation layer DL may be located between the upper surface IP2_T and the lower surface IP2_B of the second insulating pattern IP2. The second insulating pattern IP2 may surround the lowermost portion DL_L of the gate isolation layer DL.

The level of the lowermost portion DL_L of the gate isolation layer DL may be higher than that of a lower surface SS1_B of the first slit structure 551, and be higher than that of a lower surface SS2_B of the second slit structure SS2.

The gate isolation layer DL may isolate the third insulating patterns IP3 from each other in the first direction D1, isolate the fourth insulating patterns IP4 from each other in the first direction D1, and isolate the fifth insulating patterns IP5 from each other in the first direction D1. The third insulating patterns IP3 may be spaced apart from each other in the first direction D1 with the gate isolation layer DL interposed therebetween. The fourth insulating patterns IP4 may be spaced apart from each other in the first direction D1 with the gate isolation layer DL interposed therebetween. The fifth insulating patterns IP5 may be spaced apart from each other in the first direction D1 with the gate isolation layer DL interposed therebetween.

The first insulating patterns IP1 may be spaced apart from the gate isolation layer DL. The second to fifth insulating patterns IP2 to IP5 may be in contact with the gate isolation layer DL.

Some of the conductive patterns CP may be isolated from each other in the first direction D1 by the gate isolation layers DL. The conductive patterns CP isolated from each other in the first direction D1 by the gate isolation layers DL may be defined as first to fourth select lines SP1, SP2, SP3, and SM.

The first select line SP1 may be disposed between the first slit structure SS1 and the first gate isolation layer DL1, the second select line SP2 may be disposed between the first gate isolation layer DL1 and the second gate isolation layer DL2, the third select line SP3 may be disposed between the second gate isolation layer DL2 and the third gate isolation layer DL3, and the fourth select line SP4 may be disposed between the third gate isolation layer DL3 and the second slit structure SS2.

The first and second select lines SP1 and SP2 may be electrically isolated from each other by the first gate isolation layer DL1, the second and third select lines SP2 and SP3 may be electrically isolated from each other by the second gate isolation layer DL2, and the third and fourth select lines SP3 and SP4 may be electrically isolated from each other by the third gate isolation layer DL3.

A length of the first insulating pattern IP1 in the third direction D3 may be defined as a first length L1, a length of the second insulating pattern IP2 in the third direction D3 may be defined as a second length L2, a length of the third insulating pattern IP3 in the third direction D3 may be defined as a third length L3, a length of the fourth insulating pattern IP4 in the third direction D3 may be defined as a fourth length L4, and a length of the fifth insulating pattern IP5 in the third direction D3 may be defined as a fifth length L5.

The second to fourth lengths L2, L3, and L4, respectively, may be greater than the first length L1. The second to fourth lengths L2, L3, and L4 may be the same. The fifth length L5 may be greater than the second to fourth lengths L2, L3, and L4, respectively.

The second insulating pattern IP2 may have a thickness thicker than that of the first insulating patterns IP1. The second to fourth lengths L2, L3, and L4 may have the same thickness. The fifth insulating pattern IP5 may have a thickness thicker than that of the second insulating pattern IP2.

Channel structures CST penetrating the first stack structure SST1 or the second stack structure SST2 may be provided. The channel structures CST may penetrate the first to fifth insulating patterns IP1, IP2, IP3, IP4, and IP5 and the conductive patterns CR The channel structures CST may have the shape of a circular pillar. The channel structures CST may penetrate the second and third source layers SL2 and SL3. The channel structures CS may extend in the third direction D3. A lowermost portion of each of the channel structures CST may be located in the first source layer SL1.

Each of the channel structures CST may be disposed between the first slit structure SS1 and the first gate isolation layer DL1, between the first and second gate isolation layers DL1 and DL2, between the second and third gate isolation layers DL2 and DL3, or between the third gate isolation layer DL3 and the second slit structure SS2.

Each of the channel structures CST may include a filling layer FL, a conductive pad PA on the filling layer FL, a channel layer CL surrounding the filling layer FL and the conductive pad PA, and a memory layer ML surrounding the channel layer CL. The filling layer FL and the channel layer CL may penetrate the second source layer SL2. The second source layer SL2 may penetrate the memory layer ML and be in contact with a sidewall of the channel layer CL. The channel layer CL and the common source line may be electrically connected to each other by the second source layer SL2.

In an example, the filling layer FL may include silicon oxide. In an example, the channel layer CL may include doped poly-silicon or undoped poly-silicon. The memory layer ML may include a tunnel layer in contact with the channel layer CL, a storage layer surrounding the tunnel layer, and a blocking layer surrounding the storage layer. The tunnel layer may include oxide through which charges can tunnel. The storage layer may include a material in which charges can be trapped. The blocking layer may include a material capable of blocking movement of charges. In an example, the conductive pad PA may include doped poly-silicon.

As shown in the drawings, in these embodiments, the channel layer CL may have the shape of a cylinder. Unlike as shown in the drawings, in an embodiment apart from these embodiments, the channel layer CL may have the shape of a circular pillar. The filling layer FL may not be provided in the channel layer CL.

Although not shown in the drawings, bit lines extending in the first direction D1 may be provided on the first and second stacks structures SST1 and SST2. The bit lines may be electrically connected to the channel structures CST.

According to the structure described above, one memory block MB may include a plurality of slit structures SS1, SS2, and SS3 and a plurality of stack structures SST1 and SST2. One stack structure SST1 or SST2 may include a plurality of gate isolation layers DL. In addition, select lines SP1, SP2, SP3, and SP4 located at the same level may be isolated from each other by the gate isolation layers DL.

In addition, the second to fourth insulating patterns IP2, IP3, and IP4 may have thickness thicker than the first insulating pattern IP1. Thus, although the gate isolation layers DL are formed to a non-uniform depth due to a limitation in a process, the lowermost portions of the gate isolation layers DL can be located in the second insulating pattern IP2. Accordingly, a word line can be prevented from being damaged by the gate isolation DL, or the select lines SP1, SP2, SP3, and SP4 can be prevented from not being isolated from each other.

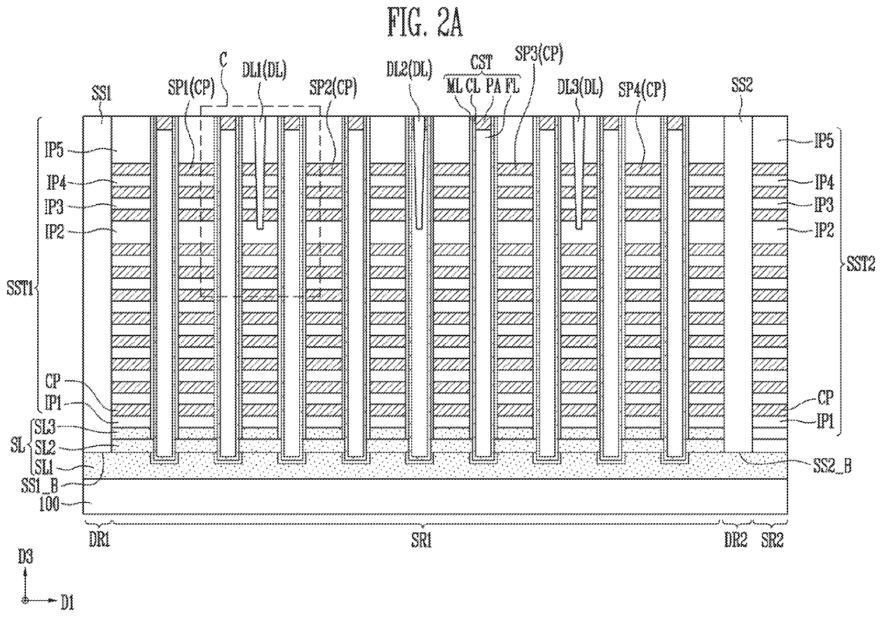

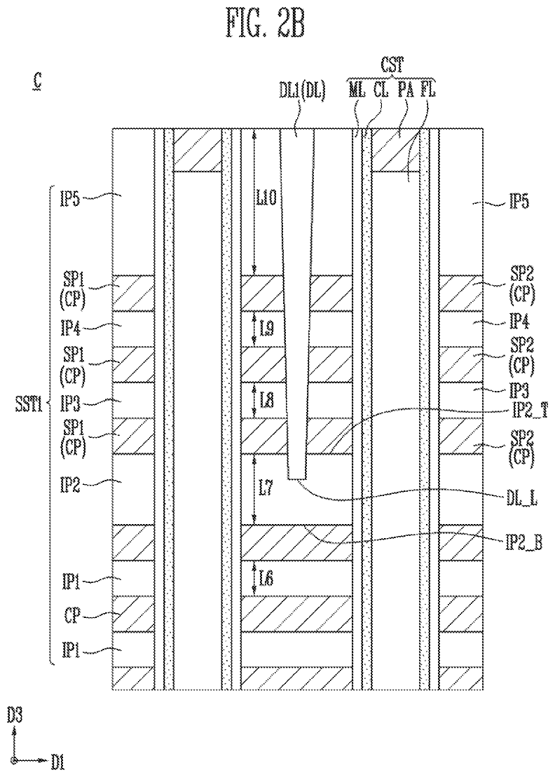

FIG. 2A is a sectional view of a semiconductor memory device in accordance with a second embodiment of the present disclosure. FIG. 2B is an enlarged view of region C shown in FIG. 2A.

The semiconductor memory device in accordance with these embodiments may be similar to the semiconductor memory devices shown in FIGS. 1A to 1C, except portions described below.

Referring to FIGS. 2A and 2B, each of a first stack structure SST1 and a second stack structure SST2 of the semiconductor memory device in accordance with these embodiments may include first to fifth insulating patterns IP1, IP2, IP3, IP4, and IP5.

A length of the first insulating pattern IP1 in a vertical direction (i.e., a third direction D3) may be defined as a sixth length L6, a length of the second insulating pattern IP2 in the vertical direction may be defined as a seventh length L7, a length of the third insulating pattern IP3 in the vertical direction may be defined as an eighth length L8, a length of the fourth insulating pattern IP4 in the vertical direction may be defined as a ninth length L9, and a length of the fifth insulating pattern IP5 in the vertical direction may be defined as a tenth length L10.

The seventh length L7 may be greater than the sixth length L6. The seventh length L7 may be greater than the eighth and ninth lengths L8 and L9, respectively. The sixth, eighth, and ninth lengths L6, L8, and L9 may be the same. The tenth length L10 may be greater than the seventh length L7.

The second insulating pattern IP2 may have a thickness thicker than those of the third and fourth insulating patterns IP3 and IP4. The third and fourth insulating patterns IP3 and IP4 may have thicknesses equal to those of the first insulating patterns IP.

According to the structures described above, the second insulating pattern IP2 may have a thickness thicker than those of the first insulating pattern IP1 and the third and fourth insulating patterns IP3 and IP4. The thickness of the fifth insulating pattern IP5 may be greater than the second insulating pattern IP2. Thus, although the gate isolation layers DL are formed to a non-uniform depth due to a limitation in a process, lowermost portions of the gate isolation layers DL can be located in the second insulating pattern IP2. Further, the thickness of the second insulating pattern IP2 is selectively increased, so that an increase in height of the stack structures SST1 and SST2 can be minimized.

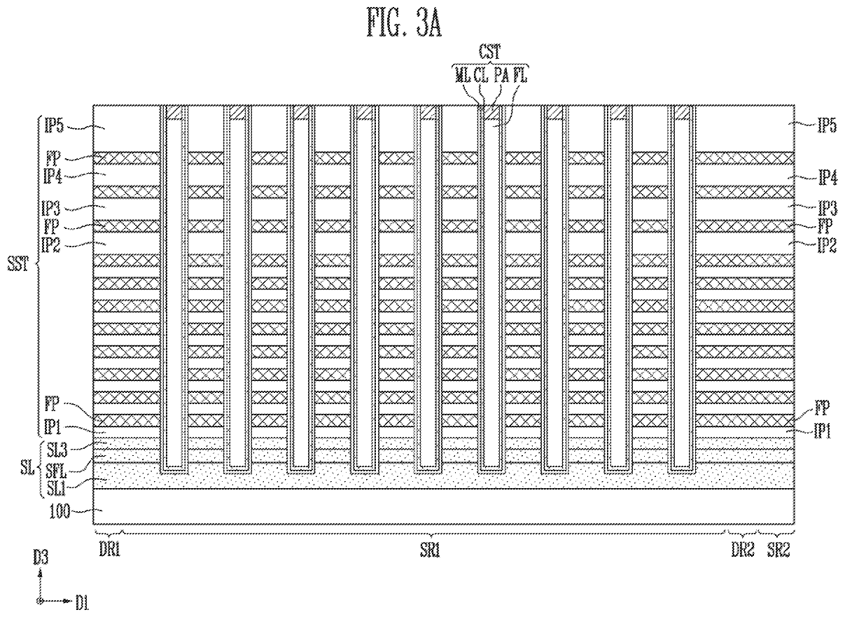

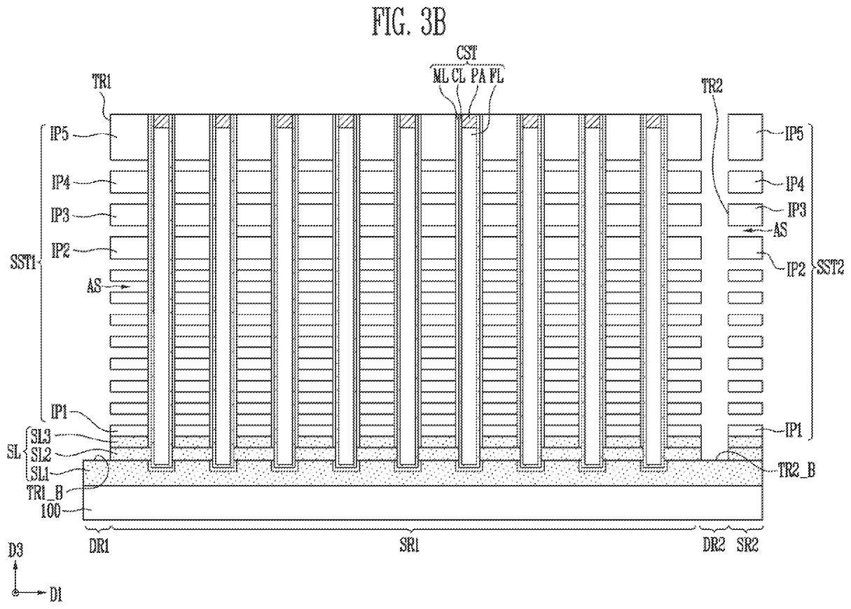

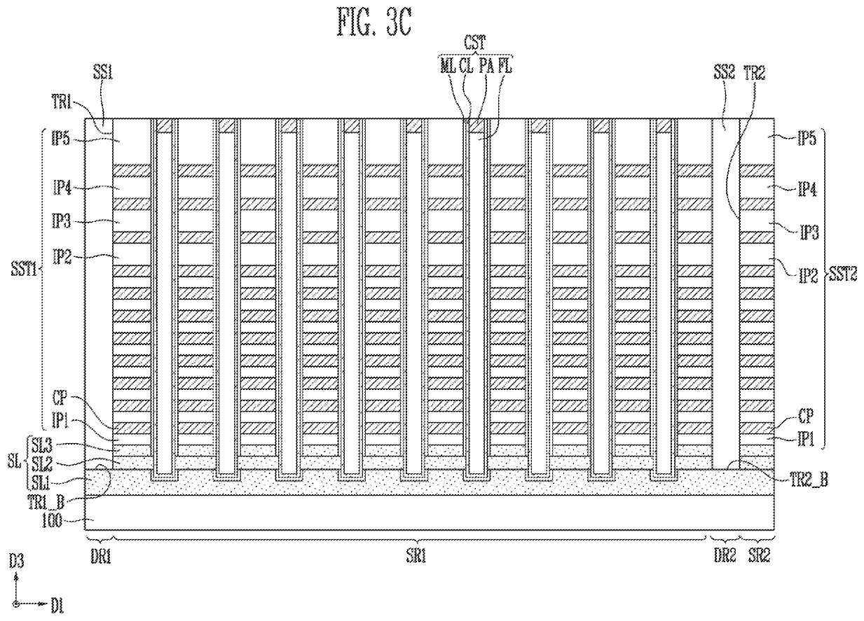

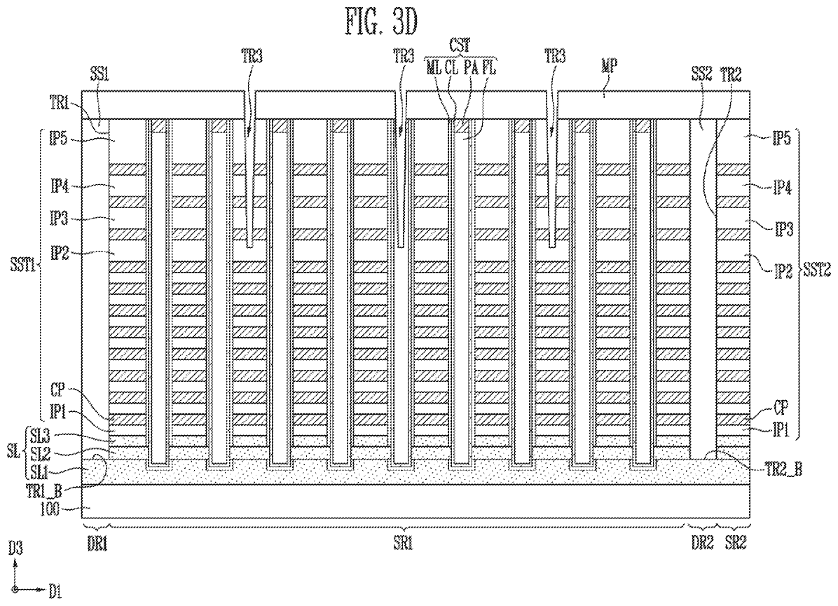

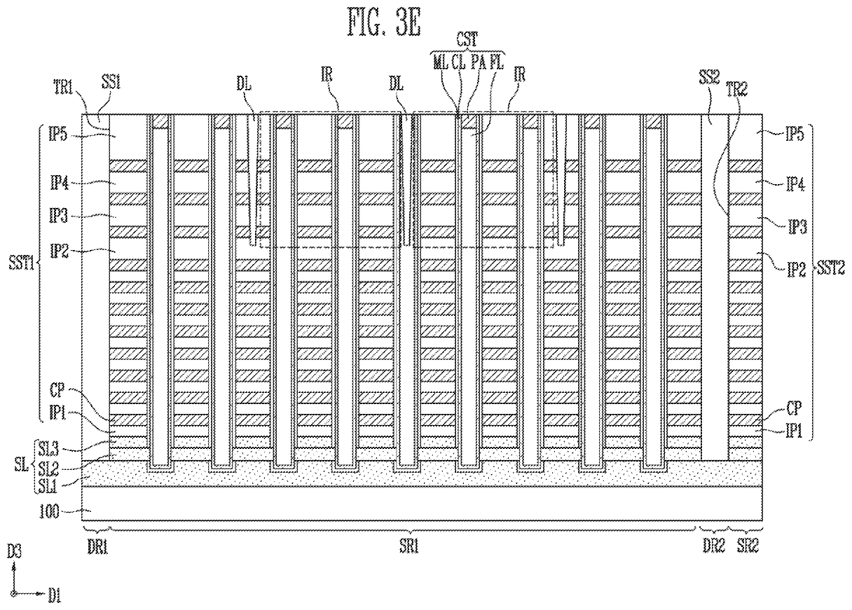

FIGS. 3A to 3E are sectional views illustrating a manufacturing method of the semiconductor memory device in accordance with the first embodiment of the present disclosure.

For convenience of description, components identical to those described with reference to FIGS. 1A to 1C are designated by like reference numerals, and overlapping descriptions will be omitted.

The manufacturing method described below is merely one embodiment of the manufacturing method of the semiconductor memory device shown in FIGS. 1A to 1C, and the manufacturing method of the semiconductor memory device shown in FIGS. 1A to 1C may not be limited to that described below.

Referring to FIG. 3A, a source structure SL may be formed on a substrate 100. The source structure SL may include a first source layer SL1, a source sacrificial layer SFL, and a third source layer SL3.

The first source layer SL1 may be formed on the substrate 100, the source sacrificial layer SFL may be formed on the first source layer SL1, and the third source layer SL3 may be formed on the source sacrificial layer SFL. In an example, the source sacrificial layer SFL may include a poly-silicon layer and a silicon oxide layer.

Subsequently, a stack structure SST may be formed on the source structure SL. The stack structure SST may be formed by alternately stacking first to fifth insulating patterns IP1, IP2, IP3, IP4, and IP5 and sacrificial patterns FR The second insulating pattern IP2 may have a thickness thicker than those of the first insulating patterns IP1. The third and fourth insulating patterns IP3 and IP4 may respectively have thicknesses thicker than that of the second insulating pattern IP2. The fifth insulating pattern IP5 may have a thickness thicker than those of the second to fourth insulating patterns IP2, IP3, and IP4, respectively. In an example, the sacrificial patterns FP may include silicon nitride.

Channel structures CST may be formed, which penetrate the first to fifth insulating patterns IP1, IP2, IP3, IP4, and IP5, the sacrificial patterns FP, the source sacrificial layer SFL, and the third source layer SL3. The process of forming the channel structures CST may include a process of forming holes penetrating the first to fifth insulating patterns IP1, IP2, IP3, IP4, and IP5, the sacrificial patterns FP, the source sacrificial layer SFL, and the third source layer SL3 and a process of sequentially filling the holes with a memory layer ML, a channel layer CL, a filling layer FL, and a conductive pad PA.

Referring to FIG. 3B, a first trench TR1 and a second trench TR2 may be formed, which extend in a second direction D2. The first trench TR1 may be formed on a first isolation layer DR1, and the second trench TR2 may be formed on a second isolation layer DR2.

The first and second trenches TR1 and TR2 may penetrate the stack structure SST. The stack structure SST may be isolated into first and second stack structures SST1 and SST2 by the first and second trenches TR1 and TR2. The first stack structure SST1 may be provided between the first and second trenches TR1 and TR2. The first and second trenches TR1 and TR2 may penetrate the first to fifth insulating patterns IP1, IP2, IP3, IP4, and IP5 and the sacrificial patterns FP.

The source structure SL may be exposed by the first and second trenches TR1 and TR2. The source sacrificial layer SFL may be replaced with a second source layer SL2 through the first and second trenches TR1 and TR2. For example, after the channel layer CL is exposed by removing the source sacrificial layer SFL and etching the memory layer ML, the second source layer SL2 may be formed. The second source layer SL2 may penetrate the memory layer ML and be in contact with the channel layer CL.

The sacrificial patterns FP exposed through the first and second trenches TR1 and TR2 may be removed. An echant may be introduced into the stack structures SST1 and SST2 through the first and second trenches TR1 and TR2, and the sacrificial patterns FP may be removed. When the sacrificial patterns FP are removed, empty spaces AS may be formed between the first to fifth insulating patterns IP1, IP2, IP3, IP4, and IP5. Since the sacrificial patterns FP are removed before a gate isolation layer DL is formed, the empty spaces AS may be formed up to the inside of the stack structures SST1 and SST2.

Referring to FIG. 3C, the empty spaces AS between the first to fifth insulating patterns IP1, IP2, IP3, IP4, and IP5 may be filled with conductive patterns CP. The sacrificial patterns FP between the first to fifth insulating patterns IP1, IP2, IP3, IP4, and IP5 may be replaced with the conductive patterns CP through the first and second trenches TR1 and TR2. Subsequently, a first slit structure SS1 may be formed in the first trench TR1, and a second slit structure SS2 may be formed in the second trench TR2.

Referring to FIG. 3D, a plurality of third trenches TR3 penetrating upper portions of the first and second stack structures SST1 and SST2 may be formed. The plurality of third trenches TR3 may be formed between the first and second trenches TR1 and TR2. The plurality of third trenches TR3 may be formed between the first and second slit structures SS1 and SS2.

The third trenches TR3 may extend in the second direction D2. The third trenches TR3 may penetrate some of the conductive patterns CP, the third insulating pattern IP3, the fourth insulating pattern IP4, and the fifth insulating pattern IP5. Each of the third to fifth insulating patterns IP3, IP4, and IP5 may be isolated into a plurality of insulating patterns by the third trenches TR3. Each of the conductive patterns CP between the second to fifth insulating patterns IP2, IP3, IP4, and IP5 may be isolated into a plurality of insulating patterns by the third trenches.

The third trench TR3 may penetrate upper portions of some of the channel structures CST. A bottom surface of the third trench TR3 may be located in the second insulating pattern IP2. The bottom surface of the third trench TR3 may have a level higher than those of a bottom surface TR1_B of the first trench TR1 and a bottom surface TR2_B of the second trench TR2.

The process of forming the third trenches TR3 may include a process of forming a mask pattern MP including an opening on the first and second stack structures SST1 and SST2 and a process of patterning the first and second stack structures SST1 and SST2 through the opening. After the first and second stack structures SST1 and SST2 are patterned, the remaining mask pattern MP may be removed.

Referring to FIG. 3E, gate isolation layers DL may be formed in the third trenches TR3. Select lines SP1, SP2, SP3, and SP4 located at the same level may be isolated from each other by the gate isolation layers DL. Lowermost portions DL_L of the gate isolation layers DL may be located in the second insulating pattern IP2.

In accordance with the manufacturing method described above, a plurality of gate isolation layers DL are formed in one stack structure SST1 or SST2. Therefore, an isolated region IR exists between adjacent gate isolation layers DL. When gate isolation layers DL are formed before the sacrificial patterns FP are replaced with the conductive patterns CP, sacrificial patterns FP between the gate isolation layers DL are isolated. The etchant introduced through the first trench TR1 and the second trench TR2 cannot reach the isolated sacrificial patterns FP, and the isolated sacrificial pattern FP cannot be replaced with the conductive patterns CR Therefore, the select lines SP1, SP2, SP3, and SP4 cannot be formed between the gate isolation layers DL. On the other hand, in accordance with these embodiments of the present disclosure, the gate isolation layers DL are formed after the sacrificial patterns FP are replaced with the conductive patterns CP, thereby solving this problem.

Meanwhile, since the gate isolation layers DL are formed after the sacrificial patterns FP are replaced with the conductive patterns CP, the third trench TR3 is formed by repeatedly etching the conductive patterns CP and the second to fifth insulating patterns IP2, IP3, IP4, and IP5. However, an etch selectivity between the conductive patterns CP including tungsten, etc. and the second to fifth insulating patterns IP2, IP3, IP4, and IP5 including oxide, etc. is small, and hence it is difficult to control the depth of the third trench TR3. Thus, in accordance with these embodiments of the present disclosure, the thickness of the second insulating pattern IP2 located at an etch stop level is increased. Accordingly, the thickness of a specific insulating pattern is increased, so that an etch margin can be secured without changing any process condition. Further, the third trenches TR3 can be prevented from being formed to a sufficient depth, or conductive patterns under the third trenches TR3 can be prevented from being damaged as the third trenches TR3 penetrate the second insulating pattern IP2.

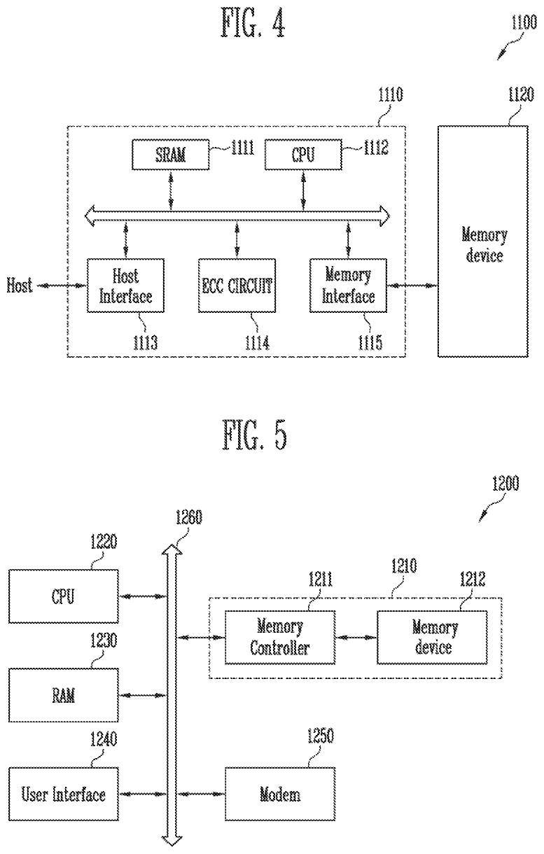

FIG. 4 is a block diagram illustrating a configuration of a memory system in accordance with an embodiment of the present disclosure.

Referring to FIG. 4, the memory system 1100 in accordance with the embodiments of the present disclosure includes a memory device 1120 and a memory controller 1110.

The memory device 1120 may include the structures described with reference to FIGS. 1A to 1C or 2A and 2B. The memory device 1120 may be a multi-chip package configured with a plurality of flash memory chips.

The memory controller 1110 is configured to control the memory device 1120, and may include a Static Random Access Memory (SRAM) 1111, a Central Processing Unit (CPU) 1112, a host interface 1113, an Error Correction Code (ECC) circuit 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The ECC circuit 1114 detects and corrects an error included in a data read from the memory device 1120, and the memory interface 1115 interfaces with the memory device 1120. In addition, the memory controller 1110 may further include an ROM for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one among various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (DATA) protocol, a Small Computer Small Interface (SCSI) protocol, an Enhanced Small Disk Interface (ESDI) protocol, and an Integrated Drive Electronics (IDE) protocol.

FIG. 5 is a block diagram illustrating a configuration of a computing system in accordance with an embodiment of the present disclosure.

Referring to FIG. 5, the computing system 1200 in accordance with the embodiments of the present disclosure may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, a Camera Image Processor (CIS), a mobile D-RAM, and the like may be further included.

The memory system 1200 may be configured with a memory device 1212 and a memory controller 1211 as described with reference to FIG. 4.

In the semiconductor memory device in accordance with the present disclosure, a length of an insulating pattern surrounding a lowermost portion of a gate isolation layer in a vertical direction can be relatively large. Accordingly, the operational reliability of the semiconductor memory device can be improved.

While the present disclosure has been shown and described with reference to various embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A method of manufacturing a semiconductor memory device, the method comprising:
forming sacrificial patterns and insulating patterns, which are alternately stacked on a source structure;
forming channel structures penetrating the sacrificial patterns and the insulating patterns;
forming a first trench and a second trench, which penetrate the sacrificial patterns and the insulating patterns;
replacing the sacrificial patterns with conductive patterns through the first and second trenches; and
forming gate isolation layers, which penetrate some of the conductive patterns and some of the insulating patterns, and are located between the first trench and the second trench,
wherein the insulating patterns include a second insulating pattern and first insulating patterns between the second insulating pattern and the source structure,
wherein lowermost portions of the gate isolation layers are located in the second insulating pattern,
wherein the second insulating pattern has a thickness thicker than those of the first insulating patterns.

2. The method of claim 1, wherein the gate isolation layers include a first gate isolation layer and a second isolation layer.

3. The method of claim 1, wherein the insulating patterns further include a third insulating pattern penetrated by the gate isolation layers,
wherein the third insulating pattern has a thickness substantially equal to that of the second insulating pattern.

4. The method of claim 1, wherein the insulating patterns further include a third insulating pattern penetrated by the gate isolation layers,
wherein the second insulating pattern has a thickness thicker than that of the third insulating pattern.

5. The method of claim 4, wherein the third insulating pattern has substantially the same thickness as the first insulating patterns, respectively.

6. The method of claim 1, further comprising:
forming a first slit structure in the first trench; and
forming a second slit structure in the second trench,
wherein at least one of the first and second slit structures includes a common source line.

7. The method of claim 6, wherein the first slit structure and the second slit structure are connected to the source structure.

8. The method of claim 1, wherein the lowermost portions of the gate isolation layers are located between upper and lower surfaces of the second insulating pattern.

9. The method of claim 1, wherein at least one of the channel structures is located between the gate isolation layers adjacent to each other.

10. The method of claim 1, wherein the lowermost portions of the gate isolation layers have a level higher than that of bottom surfaces of the first and second trenches.

11. The method of claim 1, wherein the insulating patterns further include a fifth insulating pattern located at an uppermost portion among the insulating patterns,
wherein the fifth insulating pattern has a thickness thicker than that of the second insulating pattern.

12. A semiconductor memory device comprising:
a stack structure including conductive patterns and insulating patterns, which are alternately stacked;
first and second slit structures spaced apart from each other with the stack structure interposed between the first and second slit structures;
a first gate isolation layer penetrating a portion of the stack structure, the first gate isolation layer being disposed between the first slit structure and the second slit structure;
a second gate isolation layer penetrating a portion of the stack structure, the second gate isolation layer being disposed between the first slit structure and the second slit structure; and
first channel structures penetrating the stack structure, the first channel structures being disposed between the first gate isolation layer and the second gate isolation layer,
wherein the insulating patterns include a second insulating pattern in contact with lowermost portions of the first and second gate isolation layers and first insulating patterns spaced apart from the first and second gate isolation layers,
wherein the second insulating pattern has a thickness thicker than those of the first insulating patterns.

13. The semiconductor memory device of claim 12, wherein the lowermost portions of the first and second gate isolation layers are at a level higher than that of lower surfaces of the first and second slit structures.

14. The semiconductor memory device of claim 12, wherein the conductive patterns include word lines and select lines,
wherein the first slit structure and the second slit structure penetrate the word lines and the select lines, and
the first gate isolation layer and the second gate isolation layer penetrate the select lines.

15. The semiconductor memory device of claim 12, further comprising:
second channel structures disposed between the first slit structure and the first gate isolation layer; and
third channel structures disposed between the second slit structure and the second gate isolation layer.

16. The semiconductor memory device of claim 14, wherein the select lines include a first select line, a second select line, and a third select line,
wherein the first and second select lines are electrically isolated from each other by the first gate isolation layer, and
the second and third select lines are electrically isolated from each other by the second gate isolation layer.

17. The semiconductor memory device of claim 16, wherein the first to third select lines are located at the same level.

18. The semiconductor memory device of claim 12, wherein the insulating patterns further include a third insulating pattern penetrated by the first and second gate isolation layers,
wherein the third insulating pattern has a thickness equal to that of the second insulating pattern.

19. The semiconductor memory device of claim 12, wherein the insulating patterns further include a third insulating pattern penetrated by the first and second gate isolation layers,
wherein the second insulating pattern has a thickness thicker than that of the third insulating pattern.
